(19) United States
(12) Patent Application Publication
(10) Pub. No.: US 2026/0045924 A1
(43) Pub. Date: Feb. 12, 2026

(54) ELECTRONIC DEVICE

(71) Applicant: Innolux Corporation, Miaoli County (TW)

(72) Inventor: Junya Shibata, Miaoli County (TW)

(73) Assignee: Innolux Corporation, Miaoli County (TW)

(21) Appl. No.: 18/797,516

(22) Filed: Aug. 8, 2024

(51) Int. Cl. H03F 3/45; G05F 1/56

(52) U.S. Cl. CPC H03F 3/45475; G05F 1/56; H03F 2203/45116

(57) ABSTRACT

An electronic device is provided. The electronic device includes a substrate, a voltage source, and a differential amplifier. The voltage source is disposed on the substrate. The voltage source is configured to output a first bandgap reference voltage and a second bandgap reference voltage. The differential amplifier is disposed on the substrate, and electrically connected to a voltage source. The differential amplifier includes a first sub amplifier, a second sub amplifier, and a third sub amplifier. The first sub amplifier is configured to receive the first bandgap reference voltage. The second sub amplifier is configured to receive the second bandgap reference voltage. The third sub amplifier is electrically connected to the first sub amplifier and the second sub amplifier. The first bandgap reference voltage is lower than the second bandgap reference voltage.

### BACKGROUND

### Technical Field

The disclosure relates a device; particularly, the disclosure relates to an electronic device.

### Description of Related Art

In the crystal silicon process, a bandgap reference circuit may configured to provide a reference voltage with P-N junction diode or diode connected Bipolar junction transistors (BJTs). However, in the low-temperature polycrystalline silicon process (LTPS), the bandgap reference circuit with incorporated with BJTs has too high hurdle. And, even if the diode connected thin film transistor (TFT) would be incorporated by the LTPS process, it causes output voltage variation, because the diode forward voltage (Vf) is mostly influenced by process variation.

### SUMMARY

The electronic device of the disclosure includes a substrate, a voltage source, and a differential amplifier. The voltage source is disposed on the substrate, and configured to output a first bandgap reference voltage and a second bandgap reference voltage. The differential amplifier is disposed on the substrate, and electrically connected to a voltage source. The differential amplifier includes a first sub amplifier, a second sub amplifier, and a third sub amplifier. The first sub amplifier is configured to receive the first bandgap reference voltage. The second sub amplifier is configured to receive the second bandgap reference voltage. The third sub amplifier is electrically connected to the first sub amplifier and the second sub amplifier. The first bandgap reference voltage is lower than the second bandgap reference voltage.

Based on the above, according to the electronic device of the disclosure, the electronic device may effectively generate a stable output voltage according to the first bandgap reference voltage and the second bandgap reference voltage.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of an electronic device according to an embodiment of the disclosure.

FIG. 2 is a schematic diagram of a voltage source according to an embodiment of the disclosure.

FIG. 3A is a schematic diagram of a first bandgap reference circuit according to an embodiment of the disclosure.

FIG. 3B is a schematic diagram of a first bandgap reference circuit according to another embodiment of the disclosure.

FIG. 4 is a schematic diagram of a second bandgap reference circuit according to an embodiment of the disclosure.

FIG. 5 is a schematic diagram of a bandgap reference circuit according to an embodiment of the disclosure.

FIG. 6 is a schematic diagram of a differential amplifier according to an embodiment of the disclosure.

FIG. 7 is a schematic diagram of voltage changes of a plurality of output voltages according to an embodiment of the disclosure.

FIG. 8 is a schematic diagram of a differential amplifier according to an embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like components.

Certain terms are used throughout the specification and appended claims of the disclosure to refer to specific components. Those skilled in the art should understand that electronic device manufacturers may refer to the same components by different names. This article does not intend to distinguish those components with the same function but different names. In the following description and rights request, the words such as “comprise” and “include” are open-ended terms, and should be explained as “including but not limited to . . . ”.

The term “coupling (or connection)” used throughout the whole specification of the present application (including the appended claims) may refer to any direct or indirect connection means. For example, if the text describes that a first device is coupled (or connected) to a second device, it should be interpreted that the first device may be directly connected to the second device, or the first device may be indirectly connected through other devices or certain connection means to be connected to the second device. The terms “first”, “second”, and similar terms mentioned throughout the whole specification of the present application (including the appended claims) are merely used to name discrete elements or to differentiate among different embodiments or ranges. Therefore, the terms should not be regarded as limiting an upper limit or a lower limit of the quantity of the elements and should not be used to limit the arrangement sequence of elements. In addition, wherever possible, elements/components/steps using the same reference numerals in the drawings and the embodiments represent the same or similar parts. Reference may be mutually made to related descriptions of elements/components/steps using the same reference numerals or using the same terms in different embodiments.

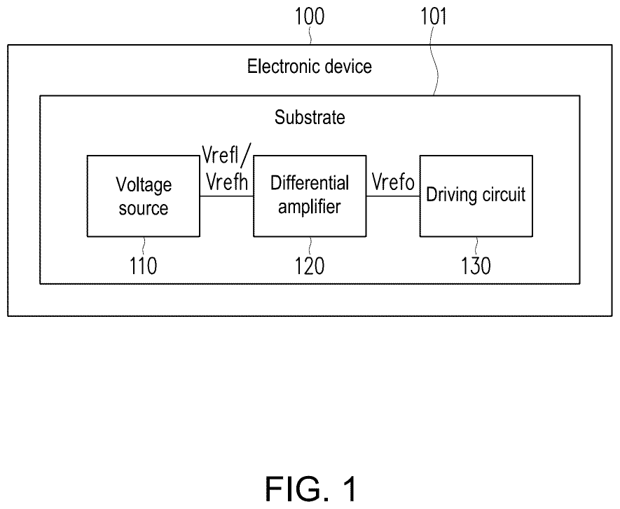

FIG. 1 is a schematic diagram of an electronic device according to an embodiment of the disclosure. Referring to FIG. 1, the electronic device 100 includes a substrate 101, a voltage source 110, a differential amplifier 120, and a driving circuit 130. The differential amplifier 120 is electrically connected to the voltage source 110 and the driving circuit 130. In the embodiment of the disclosure, the voltage source 110, the differential amplifier 120, and the driving circuit 130 are disposed on the substrate 101. The voltage source 110 may be configured to output a first bandgap reference voltage Vrefl and a second bandgap reference voltage Vrefh to the differential amplifier 120. The first bandgap reference voltage Vrefl is lower than the second bandgap reference voltage Vrefh. The differential amplifier 120 may output an output voltage Vrefo to the driving circuit 130 according to the first bandgap reference voltage Vrefl and the second bandgap reference voltage Vrefh.

In one embodiment of the disclosure, the electronic device 100 may be a display device (e.g. a liquid crystal display (LCD) or an organic light-emitting diode (OLED) display), and may further include a display panel (e.g. LCD panel or OLED panel). The driving circuit 130 may be a display driving circuit (e.g. a scan driver circuit). The driving circuit 130 may be electrically connected to the display panel, and the driving circuit 130 may be configured to drive a display panel of the display device. In one embodiment of the disclosure, the substrate 101 may be a glass substrate, and the voltage source 110, the differential amplifier 120, and the driving circuit 130 may be manufactured by a low-temperature polycrystalline silicon (LTPS) process. In other words, the thin film transistors in the voltage source 110, the differential amplifier 120, and the driving circuit have polycrystalline silicon semiconductor layers.

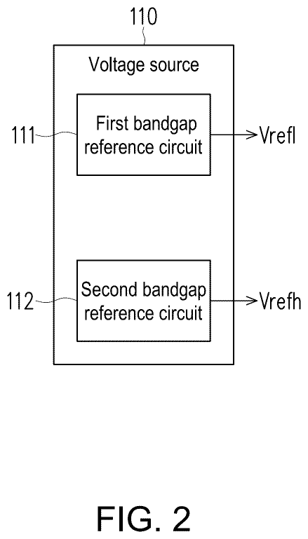

FIG. 2 is a schematic diagram of a voltage source according to an embodiment of the disclosure. Referring to FIG. 2, in the embodiment of the disclosure, the voltage source 110 of FIG. 1 may include a first bandgap reference circuit 111 and a second bandgap reference circuit 112. The first bandgap reference circuit 111 and the second bandgap reference circuit 112 are electrically connected to the differential amplifier 120. The first bandgap reference circuit 111 may be configured to output the first bandgap reference voltage Vrefl to the differential amplifier 120. The second bandgap reference circuit 112 may be configured to output the second bandgap reference voltage Vrefh to the differential amplifier 120. In addition, in one embodiment of the disclosure, the voltage source 110 of FIG. 1 may just include one bandgap reference circuit which is configured to output both the first bandgap reference voltage Vrefl and the second bandgap reference voltage Vrefh.

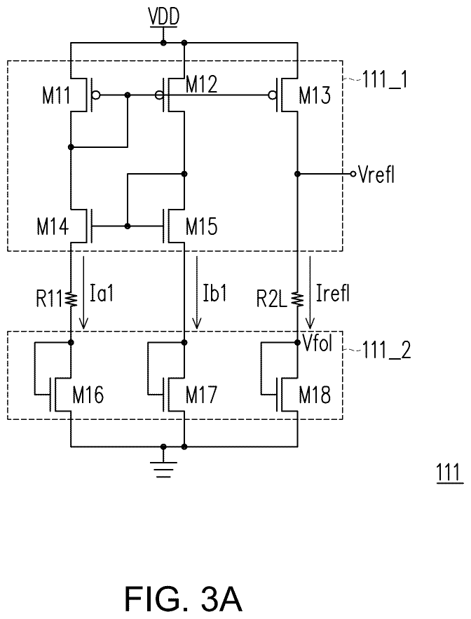

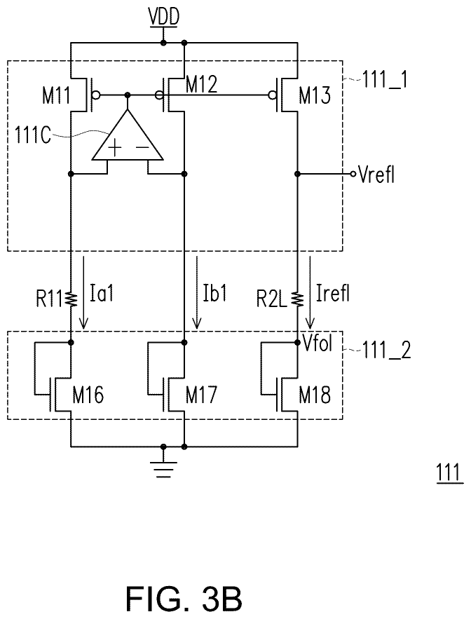

FIG. 3A is a schematic diagram of a first bandgap reference circuit according to an embodiment of the disclosure. Referring to FIG. 3A, in the embodiment of the disclosure, the first bandgap reference circuit 111 includes a current mirror circuit 111_1, a diode circuit 111_2, a resistor R11, and a resistor R2L. The current mirror circuit 111_1 is electrically connected to the diode circuit 111_2 and includes a plurality of transistors M11 to M13. The diode circuit 111_2 includes a plurality of transistors M16 to M18. In one embodiment of the disclosure, the diode circuit 111_2 may include at least one n-type thin film transistor (TFT) or at least one p-type thin film transistor. In the embodiment of the disclosure, a high voltage is electrically connected to the current mirror circuit 111_1.

In the embodiment of the disclosure, a first terminal of the transistor M11 is electrically connected to an operation voltage VDD. The operation voltage VDD may be a high voltage. A control terminal of the transistor M11 is electrically connected to a second terminal of the transistor M11, a control terminal of the transistor M12, a control terminal of the transistor M13, and a first terminal of the transistor M14. A first terminal of the transistor M12 is electrically connected to the operation voltage VDD. A second terminal of the transistor M12 is electrically connected to a first terminal of the transistor M15, a control terminal of the transistor M14, and a control terminal of the transistor M15. A first terminal of the transistor M13 is electrically connected to the operation voltage VDD. A second terminal of the transistor M13 is electrically connected to a first terminal of the resistor R2L and an output terminal of the first bandgap reference circuit 111. A second terminal of the transistor M14 is electrically connected to a first terminal of the resistor R11. A second terminal of the transistor M15 is electrically connected to a first terminal of the transistor M17 and a control terminal of the transistor M17. A first terminal of the transistor M16 is electrically connected to a second terminal of the resistor R11 and a control terminal of the transistor M16. A second terminal of the transistor M16 is electrically connected to a ground voltage. A second terminal of the transistor M17 is electrically connected to the ground voltage. A first terminal of the transistor M18 is electrically connected to a second terminal of the resistor R2L and a control terminal of the transistor M18. A second terminal of the transistor M18 is electrically connected to the ground voltage. In the embodiment of the disclosure, the transistors M11 to M13 are p-type thin film transistors, and the transistors M14 to M18 are n-type thin film transistors. In another embodiment of the disclosure, the transistors M16 to M18 may be p-type thin film transistors, and wherein the control terminals and second terminals of the transistor M16 to M18 are electrically connected to the ground voltage respectively.

In the embodiment of the disclosure, the term “diode circuit” means each of the transistors M16 to M18 may be equivalent to a diode. The transistor M16 may be equivalent to m transistors M17 connected in parallel to have m times the current capability, and the transistor M18 may be equivalent to L transistors M17 connected in parallel to have L times the current capability. Due to the current mirror circuit 111_1, a current Ia1 flowing through the transistor M16 may be controlled to be equal to a current Ib1 flowing through the transistor M17, and a reference current Irefl flowing through the transistor M18 may be controlled to be equal to the current Ib1 flowing through the transistor M17. Moreover, the reference current Irefl flows through the resistor R2L, the output terminal of the first bandgap reference circuit 111 may output a first bandgap reference voltage Vrefl, and the first terminal of the transistor M18 may have a forward voltage Vfol (i.e. the forward voltage Vfol of the equivalent diode of the transistor M18).

More specifically, the first bandgap reference voltage Vrefl and the forward voltage Vfol may satisfy the following formula (1) and formula (2). In the following formula (1) and formula (2), “Is” represents a reverse saturation current. “Vt” represents a volt equivalent of temperature, wherein

$$Vt = \frac{kT}{q} ,$$

and the “K” represents a Boltzmann's constant, “T” represents an absolute temperature, and “q” represents an absolute value of electron charge.

$$Vrefl = \frac{R 2 L}{R 11} \times Vt \times {log}_{e} ( m ) + Vfol \qquad formula ( 1 )$$

$$Vfol = Vt \times {log}_{e} ( \frac{Irefl}{L} \times \frac{1}{Is} + 1 ) \qquad formula ( 2 )$$

It should be noted that, in above formula (1) and formula (2), the term

$${}^{″} \frac{R 2 L}{R 11} \times Vt \times {log}_{e} {( m )}^{″}$$

increases as the temperature increases, but the forward voltage Vfol decreases as the temperature increases. Therefore, the first bandgap reference circuit 111 of the embodiment may have an effective temperature compensation effect. However, the reverse saturation current Is may be influenced by process variation.

FIG. 3B is a schematic diagram of a first bandgap reference circuit according to another embodiment of the disclosure. Referring to FIG. 3B, in another embodiment of the disclosure, the first bandgap reference circuit 111 includes a current mirror circuit 111_1, a diode circuit 111_2, a resistor R11, and a resistor R2L. The current mirror circuit 111_1 includes a plurality of transistors M11 to M13, and a comparator 111C. The diode circuit 111_2 includes a plurality of transistors M16 to M18. In one embodiment of the disclosure, the diode circuit 111_2 may include at least one n-type thin film transistor or at least one p-type thin film transistor.

In the embodiment of the disclosure, a first terminal of the transistor M11 is electrically connected to an operation voltage VDD. A second terminal of the transistor M11 is electrically connected to a non-inverting input terminal of the comparator 111C and a first terminal of the resistor R11. A control terminal of the transistor M11 is electrically connected to an output terminal of the comparator 111C, a control terminal of the transistor M12, and a control terminal of the transistor M13. A first terminal of the transistor M12 is electrically connected to the operation voltage VDD. A second terminal of the transistor M12 is electrically connected to an inverting input terminal of the comparator 111C and a first terminal of the transistor M17. A first terminal of the transistor M13 is electrically connected to the operation voltage VDD. A second terminal of the transistor M13 is electrically connected to a first terminal of the resistor R2L, and an output terminal of the first bandgap reference circuit 111. A first terminal of the transistor M16 is electrically connected to a second terminal of the resistor R1 and a control terminal of the transistor M16. A second terminal of the transistor M16 is electrically connected to a ground voltage. A second terminal of the transistor M17 is electrically connected to the ground voltage. A first terminal of the transistor M18 is electrically connected to a second terminal of the resistor R2L and a control terminal of the transistor M18. A second terminal of the transistor M18 is electrically connected to the ground voltage. In the embodiment of the disclosure, the transistors M11 to M13 are p-type thin film transistors, and the transistors M16 to M18 are n-type thin film transistors. In another embodiment of the disclosure, the transistors M16 to M18 may be p-type thin film transistors, and wherein the control terminals and second terminals of the transistor M16 to M18 are electrically connected to the ground voltage respectively.

However, for the specific implementation and technical details of the first bandgap reference circuit 111 of the embodiment, please refer to the descriptions of the embodiments of FIG. 3A to obtain sufficient teachings, suggestions, and implementation illustrations, which will not be reiterated here.

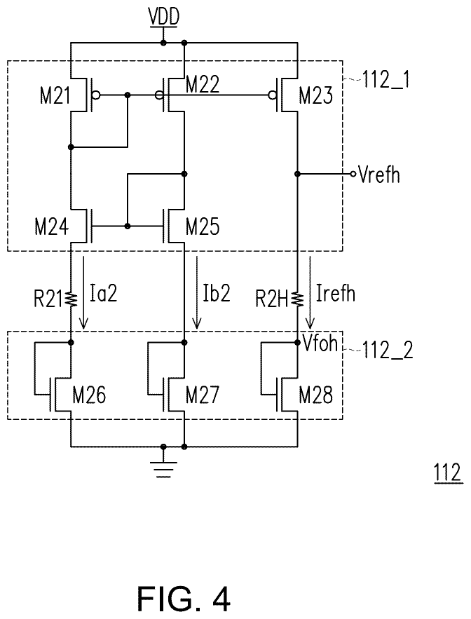

FIG. 4 is a schematic diagram of a second bandgap reference circuit according to an embodiment of the disclosure. Referring to FIG. 4, in the embodiment of the disclosure, the second bandgap reference circuit 112 includes a current mirror circuit 112_1, a diode circuit 112_2, a resistor R21, and a resistor R2H. The current mirror circuit 112_1 includes a plurality of transistors M21 to M25. The diode circuit 112_2 includes a plurality of transistors M26 to M28. In one embodiment of the disclosure, the diode circuit 112_2 may include at least one n-type thin film transistor or at least one p-type thin film transistor.

Since the circuit structure of the second bandgap reference circuit 112 is similar to the circuit structure of the first bandgap reference circuit 111 which is shown in FIG. 3A, the electrical connection between the transistors M21 to M28 will not be described again.

Similar to the transistors M16 to M18 in the first bandgap reference circuit, each of the transistors M26 to M28 may be equivalent to a diode. The transistor M26 may be equivalent to m transistors M27 connected in parallel to have m times the current capability, and the transistor M28 may be equivalent to K transistors M27 connected in parallel to have K times the current capability. Due to the current mirror circuit 112_1, a current Ia2 flowing through the transistor M26 may be controlled to be equal to a current Ib2 flowing through the transistor M27, and a reference current Irefh flowing through the transistor M28 may be controlled to be equal to the current Ib2 flowing through the transistor M27. Moreover, the reference current Irefh flows through the resistor R2H, so the output terminal of the second bandgap reference circuit 112 may output a second bandgap reference voltage Vrefh, and the first terminal of the transistor M28 may have a forward voltage Vfoh (i.e. the forward voltage Vfoh of the equivalent diode of the transistor M28).

More specifically, the second bandgap reference voltage Vrefh and the forward voltage Vfoh may satisfy the following formula (3) and formula (4).

$$Vrefh = \frac{R 2 H}{R 21} \times Vt \times {log}_{e} ( m ) + Vfoh \qquad formula ( 3 )$$

$$Vfoh = Vt \times {log}_{e} ( \frac{Irefh}{K} \times \frac{1}{Is} + 1 ) \qquad formula ( 4 )$$

It should be noted that, in above formula (3) and formula (4), the term

$${}^{″} \frac{R 2 H}{R 21} \times Vt \times {{log}_{e} ( m )}^{″}$$

increases as the temperature increases, and the forward voltage Vfoh decreases as the temperature increases. Therefore, the first bandgap reference circuit 111 of the embodiment may have an effective temperature compensation effect. However, the reverse saturation current Is may be influenced by process variation.

Furthermore, the above parameter L is higher than the above parameter K. The resistance of the resistor R2L is lower than the resistance of the resistor R2H. In addition, in one embodiment of the disclosure, the current mirror circuit 112_1 may further include a comparator, and the electrically connection manner is the same as the comparator 111C in FIG. 3B.

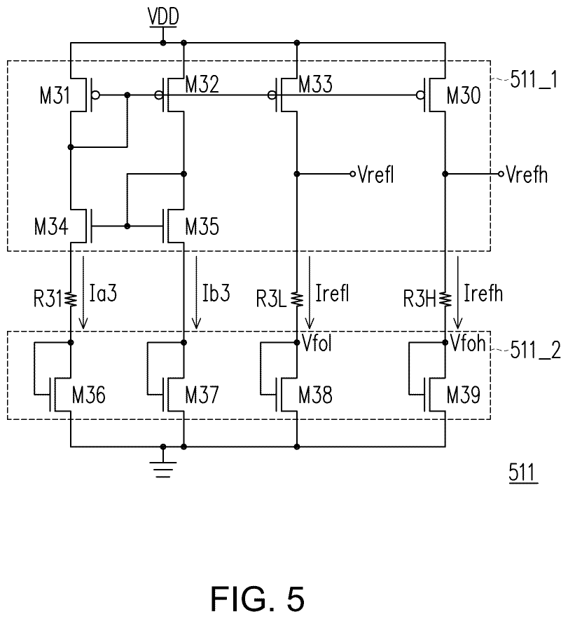

FIG. 5 is a schematic diagram of a bandgap reference circuit according to an embodiment of the disclosure. Referring to FIG. 5, in one embodiment of the disclosure, the voltage source 110 of FIG. 1 may just include one bandgap reference circuit, and the one bandgap reference circuit may be implemented as a bandgap reference circuit 511 of FIG. 5. In the embodiment of the disclosure, the bandgap reference circuit 511 includes a current mirror circuit 511_1, a diode circuit 511_2, a resistor R31, a resistor R3L, and a resistor R3H. The current mirror circuit 511_1 includes a plurality of transistors M30 to M35. The diode circuit 511_2 includes a plurality of transistors M36 to M39. In the embodiment of the disclosure, the bandgap reference circuit 511 may output a first bandgap reference voltage Vrefl and a second bandgap reference voltage Vrefh.

In the embodiment of the disclosure, a first terminal of the transistor M31 is electrically connected to an operation voltage VDD. A second terminal of the transistor M31 is electrically connected to a control terminal of the transistor M30, a control terminal of the transistor M31, a control terminal of the transistor M32, a control terminal of the transistor M33, and a first terminal of the transistor M34. A first terminal of the transistor M32 is electrically connected to the operation voltage VDD. A second terminal of the transistor M32 is electrically connected to a first terminal of the transistor M35, a control terminal of the transistor M34, and a control terminal of the transistor M35. A first terminal of the transistor M33 is electrically connected to the operation voltage VDD. A second terminal of the transistor M33 is electrically connected to a first terminal of the resistor R3L, and a first output terminal of the bandgap reference circuit 511. A second terminal of the transistor M34 is electrically connected to a first terminal of the resistor R31. A second terminal of the transistor M35 is electrically connected to a first terminal of the transistor M37 and a control terminal of the transistor M37. A first terminal of the transistor M36 is electrically connected to a second terminal of the resistor R31 and a control terminal of the transistor M36. A second terminal of the transistor M36 is electrically connected to a ground voltage. A second terminal of the transistor M37 is electrically connected to the ground voltage. A first terminal of the transistor M38 is electrically connected to a second terminal of the resistor R3L and a control terminal of the transistor M38. A second terminal of the transistor M38 is electrically connected to the ground voltage. A first terminal of the transistor M30 is electrically connected to the operation voltage VDD. A second terminal of the transistor M30 is electrically connected to a first terminal of the resistor R3H, and a second output terminal of the bandgap reference circuit 511. A first terminal of the transistor M39 is electrically connected to a second terminal of the resistor R3H and a control terminal of the transistor M39. A second terminal of the transistor M39 is electrically connected to the ground voltage. In the embodiment of the disclosure, the transistors M30 to M33 are p-type thin film transistors, and the transistors M34 to M39 are n-type thin film transistors.

In the embodiment of the disclosure, the transistors M36 to M39 may each be equivalent to a diode. The transistor M36 may be equivalent to m transistors M37 connected in parallel to have m times the current capability, the transistor M38 may be equivalent to L transistors M37 connected in parallel to have L times the current capability, and the transistor M39 may be equivalent to K transistors M37 connected in parallel to have K times the current capability. Due to the current mirror circuit 511_1, a current Ia3 flowing through the transistor M36 may be controlled to be equal to a current Ib3 flowing through the transistor M37, a reference current Irefl flowing through the transistor M38 may be controlled to be equal to the current Ib3 flowing through the transistor M37, and a reference current Irefh flowing through the transistor M39 may be controlled to be equal to the current Ib3 flowing through the transistor M37.

Moreover, the reference current Irefl flows through the resistor R3L, the first output terminal of the bandgap reference circuit 511 may output the first bandgap reference voltage Vrefl, and the first terminal of the transistor M38 may have a forward voltage Vfol (i.e. the forward voltage Vfol of the equivalent diode of the transistor M38). Similarly, the reference current Irefh flows through the resistor R3H, the second output terminal of the bandgap reference circuit 511 may output the second bandgap reference voltage Vrefh, and the first terminal of the transistor M39 may have a forward voltage Vfoh (i.e. the forward voltage Vfoh of the equivalent diode of the transistor M38). Furthermore, the above parameter L is higher than the above parameter K. The resistance of the resistor R3L is lower than the resistance of the resistor R3H.

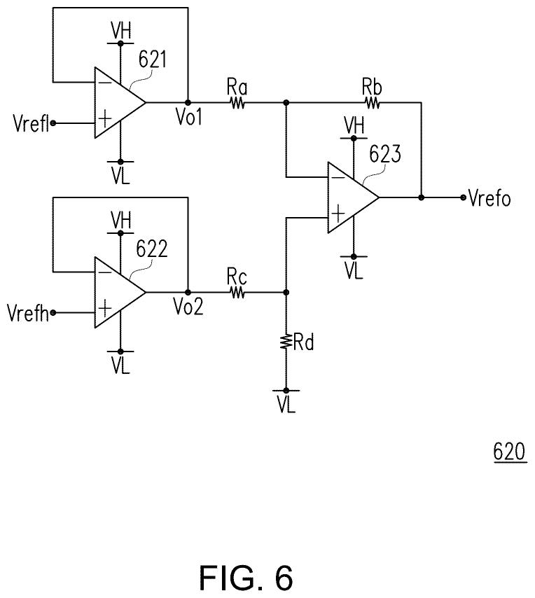

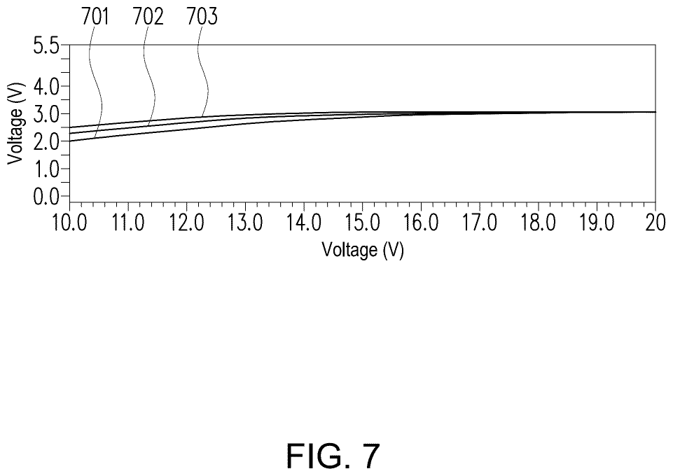

FIG. 6 is a schematic diagram of a differential amplifier according to an embodiment of the disclosure. FIG. 7 is a schematic diagram of voltage changes of a plurality of output voltages according to an embodiment of the disclosure. Referring to FIG. 6, the differential amplifier 120 of FIG. 1 may be implemented as a differential amplifier 620 of FIG. 6. In the embodiment of the disclosure, the differential amplifier 620 includes a first sub amplifier 621, a second sub amplifier 622, a third sub amplifier 623, and resistors Ra to Rd. The first sub amplifier 621 is configured to receive the first bandgap reference voltage Vrefl. The second sub amplifier 622 is configured to receive the second bandgap reference voltage Vrefh. The third sub amplifier 623 is electrically connected to the first sub amplifier 621 and the second sub amplifier 622.

Specifically, in the embodiment of the disclosure, the first sub amplifier 621, the second sub amplifier 622, and the third sub amplifier 623 respectively includes a non-inverting input terminal, an inverting input terminal, a high voltage terminal, a low voltage terminal, and an output terminal. A high voltage VH is electrically connected to the high voltage terminals of the first sub amplifier 621, the second sub amplifier 622, and the third sub amplifier 623. A low voltage VL is electrically connected to the low voltage terminals of the first sub amplifier 621, the second sub amplifier 622, and the third sub amplifier 623.

The first sub amplifier 621 receives the first bandgap reference voltage Vrefl through the non-inverting input terminal of the first sub amplifier 621, and provides a first output voltage Vo1 through the output terminal of the first sub amplifier 621. The inverting input terminal of the first sub amplifier 621 is electrically connected to the output terminal of the first sub amplifier 621 and a first terminal of the resistor Ra. The second sub amplifier 622 receives the second bandgap reference voltage Vrefh through the non-inverting input terminal of the second sub amplifier 622, and provides a second output voltage Vo2 through the output terminal of the second sub amplifier 622. The inverting input terminal of the first sub amplifier 622 is electrically connected to the output terminal of the first sub amplifier 622 and a first terminal of the resistor Rc. The third sub amplifier 623 receives the first output voltage Vo1 through the inverting input terminal of the third sub amplifier 623, and receives the second output voltage Vo2 through the non-inverting input terminal of the third sub amplifier 623.

A second terminal of the resistor Ra is electrically connected to the inverting input terminal of the third sub amplifier 623 and a first terminal of the resistor Rb. A second terminal of the resistor Rb is electrically connected to the output terminal of the third sub amplifier 623. A second terminal of the resistor Rc is electrically connected to the non-inverting input terminal of the third sub amplifier 623 and a first terminal of the resistor Rd. A second terminal of the resistor Rd is electrically connected to the low voltage VL. The output terminal of the third sub amplifier 623 may provide the output voltage Vrefo through the output terminal of the third sub amplifier 623. It should be noted that the “low voltage” in this disclosure may be referred to the ground voltage or a certain voltage lower than the high voltage VH.

In the embodiment of the disclosure, the first sub amplifier 621 and the second sub amplifier 622 may receive the first bandgap reference voltage Vrefl and the second bandgap reference voltage Vrefh from the first bandgap reference circuit 111 of FIG. 3A and the second bandgap reference circuit 112 of FIG. 4, and resistance of the resistor R11 is equal to resistance of the resistor R21. Thus, referring to the above formulas (1) to (4), the output voltage Vrefo outputted by the differential amplifier 620 may satisfy the following formula (5).

$$Vrefo = \{ Vrefh - Vrefl \} \times A = \{ \frac{R 2 H}{R 21} \times Vt \times {log}_{e} ( m ) + Vfoh - ( \frac{R 2 L}{R 11} \times Vt \times {log}_{e} ( m ) + Vfol ) \} \times A = \{ \frac{( R 2 H - R 2 L )}{R 11} \times Vt \times {log}_{e} ( m ) + Vt \times {log}_{e} ( \frac{Irefh}{k} \times \frac{1}{Is} + 1 ) - Vt \times {log}_{e} ( \frac{Irefl}{l} \times \frac{1}{Is} + 1 ) \} \times A \qquad formula ( 5 )$$

In the above formula (5), “A” represents an amplification gain of the differential amplifier 620. In one embodiment of the disclosure, the above currents in the above formula (5) may be controlled to be equal. That is, the current Irefh is much greater than the reverse saturation current Is. The current Irefl is much greater than the reverse saturation current Is. The reference current Irefh is equal to the reference current Irefl. Thus, the above formula (5) may be deduced as the following formula (6).

$$Vrefo = \{ \frac{( R 2 H - R 2 L )}{R 11} \times Vt \times {log}_{e} ( m ) + Vt \times {log}_{e} ( \frac{1}{k} ) \} \times A \qquad formula ( 6 )$$

Therefore, in the above formula (6), the output voltage Vrefo is not influenced by process variation (i.e. the reverse saturation current is removed) with keeping cancel temperature variation. Referring to FIG. 7, in one embodiment of the disclosure, curves 701 to 703 represent voltage changes of the output voltage Vrefo under different process variation. As shown in FIG. 7, the voltages of the curves 701 to 703 is stable in different operation voltage VDD from 15 volt to 20 volt.

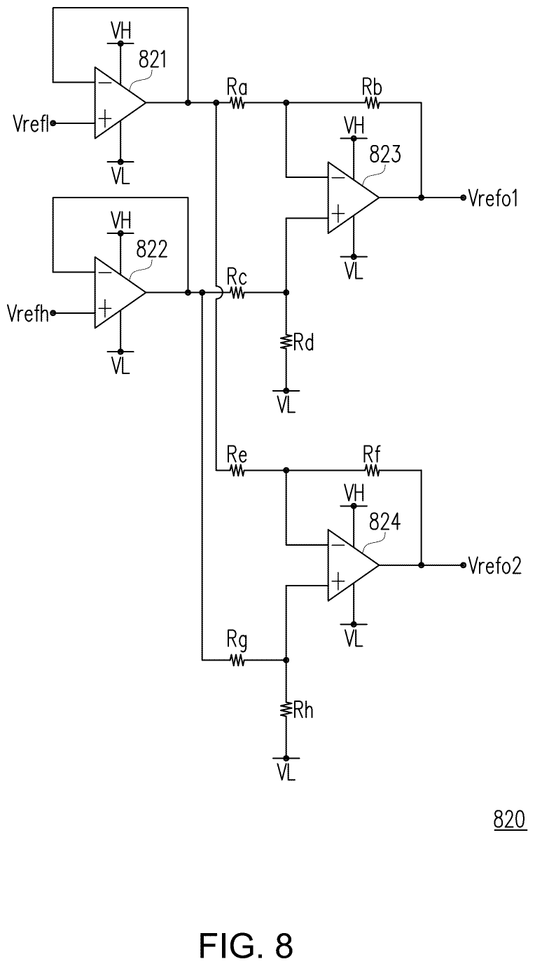

FIG. 8 is a schematic diagram of a differential amplifier according to an embodiment of the disclosure. Referring to FIG. 8, in one embodiment of the disclosure, the differential amplifier 120 of FIG. 1 may be implemented as a differential amplifier 820 of FIG. 8. In the embodiment of the disclosure, the differential amplifier 820 includes a first sub amplifier 821, a second sub amplifier 822, a third sub amplifier 823, a fourth sub amplifier 824, and resistors Ra to Rh. The first sub amplifier 821 is configured to receive the first bandgap reference voltage Vrefl. The second sub amplifier 822 is configured to receive the second bandgap reference voltage Vrefh. The third sub amplifier 823 and the fourth sub amplifier 824 are electrically connected to the first sub amplifier 821 and the second sub amplifier 822.

Specifically, in the embodiment of the disclosure, the first sub amplifier 821, the second sub amplifier 822, the third sub amplifier 823, and the fourth sub amplifier 824 respectively includes a non-inverting input terminal, an inverting input terminal, a high voltage terminal, a low voltage terminal, and an output terminal. A high voltage VH is electrically connected to the high voltage terminals of the first sub amplifier 821, the second sub amplifier 822, the third sub amplifier 823, and the fourth sub amplifier 824. A low voltage VL is electrically connected to the low voltage terminals of the first sub amplifier 821, the second sub amplifier 822, the third sub amplifier 823, and the fourth sub amplifier 824. It should be noted that in the present disclosure, the high voltage VH may be equal to the operation voltage VDD which is electrically connected to the bandgap reference circuit. In other words, in the present disclosure, the voltage source has a bandgap reference circuit, the bandgap reference circuit has a diode circuit and a current mirror circuit, and the high voltage VH is electrically connected to the current mirror circuit, the high voltage terminals of the first sub amplifier, the second sub amplifier, and the third sub amplifier.

The first sub amplifier 821 receives the first bandgap reference voltage Vrefl through the non-inverting input terminal of the first sub amplifier 821, and provides a first output voltage Vo1 through the output terminal of the first sub amplifier 821. The inverting input terminal of the first sub amplifier 821 is electrically connected to the output terminal of the first sub amplifier 821, a first terminal of the resistor Ra, and a first terminal of the resistor Re. The second sub amplifier 822 receives the second bandgap reference voltage Vrefh through the non-inverting input terminal of the second sub amplifier 822, and provides a second output voltage Vo2 through the output terminal of the second sub amplifier 822. The inverting input terminal of the first sub amplifier 822 is electrically connected to the output terminal of the first sub amplifier 822, a first terminal of the resistor Rc, and a first terminal of the resistor Rg.

The third sub amplifier 823 receives the first output voltage Vo1 through the inverting input terminal of the third sub amplifier 823, and receives the second output voltage Vo2 through the non-inverting input terminal of the third sub amplifier 823. The fourth sub amplifier 824 receives the first output voltage Vo1 through the inverting input terminal of the fourth sub amplifier 824, and receives the second output voltage Vo2 through the non-inverting input terminal of the fourth sub amplifier 824.

A second terminal of the resistor Ra is electrically connected to the inverting input terminal of the third sub amplifier 823 and a first terminal of the resistor Rb. A second terminal of the resistor Rb is electrically connected to the output terminal of the third sub amplifier 823. A second terminal of the resistor Rc is electrically connected to the non-inverting input terminal of the third sub amplifier 823 and a first terminal of the resistor Rd. A second terminal of the resistor Rd is electrically connected to the low voltage VL. The output terminal of the third sub amplifier 823 may provide the output voltage Vrefo1 through the output terminal of the third sub amplifier 823.

A second terminal of the resistor Re is electrically connected to the inverting input terminal of the fourth sub amplifier 824 and a first terminal of the resistor Rf. A second terminal of the resistor Rf is electrically connected to the output terminal of the fourth sub amplifier 824. A second terminal of the resistor Rg is electrically connected to the non-inverting input terminal of the fourth sub amplifier 824 and a first terminal of the resistor Rh. A second terminal of the resistor Rh is electrically connected to the low voltage VL. The output terminal of the fourth sub amplifier 824 may provide the output voltage Vrefo2 through the output terminal of the fourth sub amplifier 824. It should be noted that the “low voltage” herein may be referred to the ground voltage or a certain voltage lower than the high voltage VH.

In the embodiment of the disclosure, the differential amplifier 820 may provide the two output voltages Vrefo1 and Vrefo2 according to the first bandgap reference voltage Vrefl and the second bandgap reference voltage Vrefh, and the two output voltages Vrefo1 and Vrefo2 are not influenced by process variation (i.e. an influence from the reverse saturation current is removed) with keeping cancel temperature variation.

In summary, according to the electronic device of the disclosure, the electronic device may generate two bandgap reference voltages for further generate the stable output voltage to the driving circuit, and the output voltage is not influenced by process variation and temperature variation.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a substrate;
a voltage source, disposed on the substrate, and configured to output a first bandgap reference voltage and a second bandgap reference voltage; and
a differential amplifier, disposed on the substrate, and electrically connected to the voltage source, wherein the differential amplifier comprises:
a first sub amplifier, configured to receive the first bandgap reference voltage;
a second sub amplifier, configured to receive the second bandgap reference voltage; and
a third sub amplifier, electrically connected to the first sub amplifier and the second sub amplifier,
wherein the first bandgap reference voltage is lower than the second bandgap reference voltage.

2. The electronic device according to claim 1, wherein the voltage source and the differential amplifier comprise polycrystalline silicon semiconductor layers.

3. The electronic device according to claim 1, wherein the voltage source comprises:
a first bandgap reference circuit, configured to output the first bandgap reference voltage; and
a second bandgap reference circuit, configured to output the second bandgap reference voltage.

4. The electronic device according to claim 3, wherein the first bandgap reference circuit and the second bandgap reference circuit respectively comprise a diode circuit and a current mirror circuit electrically connected to the diode circuit.

5. The electronic device according to claim 4, wherein the diode circuit of one of the first bandgap reference circuit and the second bandgap reference circuit comprises at least one n-type thin film transistor.

6. The electronic device according to claim 4, wherein the diode circuit of one of the first bandgap reference circuit and the second bandgap reference circuit comprises at least one p-type thin film transistor.

7. The electronic device according to claim 4, wherein the current mirror of one of the first bandgap reference circuit and the second bandgap reference circuit comprises a first thin film transistor and a second thin film transistor, and a control terminal of the first thin film transistor is electrically connected to a control terminal of the second thin film transistor.

8. The electronic device according to claim 4, wherein the current mirror circuit of one of the first bandgap reference circuit and the second bandgap reference circuit comprises a comparator.

9. The electronic device according to claim 4, wherein the first bandgap reference circuit and the second bandgap reference circuit respectively further comprise at least one resistor, and the at least one resistor is electrically connected to the diode circuit and the current mirror circuit.

10. The electronic device according to claim 1, wherein the voltage source comprises:
a bandgap reference circuit, configured to output the first bandgap reference voltage and the second bandgap reference voltage.

11. The electronic device according to claim 1, wherein the first sub amplifier, the second sub amplifier, and the third sub amplifier respectively comprise a non-inverting input terminal, an inverting input terminal, a high voltage terminal, a low voltage terminal, and an output terminal.

12. The electronic device according to claim 11, wherein the first sub amplifier receives the first bandgap reference voltage through the non-inverting input terminal of the first sub amplifier, and provides a first output voltage through the output terminal of the first sub amplifier,
wherein the second sub amplifier receives the second bandgap reference voltage through the non-inverting input terminal of the second sub amplifier, and provides a second output voltage through the output terminal of the second sub amplifier.

13. The electronic device according to claim 12, wherein the third sub amplifier receives the first output voltage through the inverting input terminal of the third sub amplifier, and receives the second output voltage through the non-inverting input terminal of the third sub amplifier, and provides a third output voltage through the output terminal of the third sub amplifier.

14. The electronic device according to claim 13, further comprises:
a driving circuit, disposed on the substrate, wherein the driving circuit receives the third output voltage.

15. The electronic device according to claim 14, wherein the driving circuit is a display driving circuit.

16. The electronic device according to claim 12, further comprising:
a fourth sub amplifier, comprising a non-inverting input terminal, an inverting input terminal, a high voltage terminal, a low voltage terminal, and an output terminal,
wherein the fourth sub amplifier receives the first output voltage through the inverting input terminal of the fourth sub amplifier, and receives the second output voltage through the non-inverting input terminal of the fourth sub amplifier, and provides a fourth output voltage through the output terminal of the fourth sub amplifier.

17. The electronic device according to claim 11, wherein a high voltage is electrically connected to the high voltage terminals of the first sub amplifier, the second sub amplifier, and the third sub amplifier.

18. The electronic device according to claim 11, wherein the inverting input terminal of one of the first sub amplifier, the second sub amplifier, and the third sub amplifier is electrically connected to the output terminal of the one of the first sub amplifier, the second sub amplifier, and the third sub amplifier.

19. The electronic device according to claim 11, wherein a low voltage is electrically connected to the low voltage terminals of the first sub amplifier, the second sub amplifier, and the third sub amplifier.

20. The electronic device according to claim 11, wherein the voltage source comprises a bandgap reference circuit, and the bandgap reference circuit has a diode circuit and a current mirror circuit,
wherein a high voltage is electrically connected to the current mirror circuit, the high voltage terminals of the first sub amplifier, the second sub amplifier, and the third sub amplifier.
